(19) United States
(12) Patent Application Publication
(10) Pub. No.: US 2009/0189226 A1
(43) Pub. Date: Jul. 30, 2009

(54) ELECTRICAL FUSE CIRCUIT

(76) Inventors: Yasue YAMAMOTO, Osaka (JP); Yasuhiro Agata, Osaka (JP); Masanori Shirahama, Shiga (JP); Toshiaki Kawasaki, Osaka (JP)

Correspondence Address: MCDERMOTT WILL & EMERY LLP, 600 13TH STREET, NW, WASHINGTON, DC, 20005-3096, US

(21) Appl. No.: 12/247,647

(22) Filed: Oct. 8, 2008

(30) Foreign Application Priority Data
Jan. 28, 2008 (JP) 2008-015872

(51) Int. Cl. H01L 29/00

(52) U.S. Cl. 257/379; 257/E29.001

(57) ABSTRACT

An electrical fuse circuit includes, in addition to an independent power supply switch circuit, a plurality of fuse bit cells, each including a fuse element one end of which is connected to an output of the power supply switch circuit, and a first MOS transistor connected to the other end of the fuse element, wherein a diode is connected between the ground potential and the power supply switch circuit as an ESD countermeasure. The gate oxide film thickness of transistors of the fuse bit cells is equal to that of a low-voltage logic-type transistor, not that of a high-voltage I/O-type transistor.

### BACKGROUND OF THE INVENTION

1. Field of the Invention

The present invention relates to an electrical fuse circuit used as an OTP (One-Time-Programmable) memory.

2. Description of the Background Art

Electrical fuse circuits have been realized in the art, where each fuse element is programmed by passing or not passing a current through the fuse element so as to or not to break the fuse element, and such electrical fuse circuits have widely been used as program devices for trimming high-frequency semiconductor devices. Specifically, a conventional electrical fuse circuit includes a polysilicon electrical fuse element, and a bipolar transistor for passing a current for breaking the electrical fuse element, wherein the bipolar transistor is used to pass a large current of about 1 A (ampere) through the electrical fuse element to thereby break the electrical fuse element.

Recently, in the field of semiconductor integrated circuits (LSIs), a technique has been developed for forming a silicide layer on a polysilicon layer to thereby reduce the resistance of a gate electrode. An electrical fuse element has been developed in the art by using this technique, including a polysilicon layer and a silicide layer formed on the polysilicon layer, wherein the electrical fuse element has a low resistance when the silicide layer is unbroken and has a high resistance when the silicide layer is broken by a current flow therethrough (see, for example, U.S. Pat. No. 5,708,291).

With the electrical fuse element, the instantaneous current required for breaking the silicide layer is about 10 to 30 mA (milliamperes) for the 130 nm or 90 nm process generation.

In a case where such electrical fuse elements using silicide are employed for a program device for trimming a high-frequency semiconductor device, or the like, the number of electrical fuse elements to be provided on each chip is four to eight, and it is therefore possible to break all the electrical fuse elements at once using a conventional general-purpose tester.

Metal fuses have conventionally been used as fuse elements for redundancy in LSIs such as DRAMs and SRAMs. Such metal fuses may be replaced by electrical fuse elements using silicide as described above. However, this has problems as follows.

First, the number of fuse elements to be provided on each chip for RAM redundancy is 500 to 1,000. Breaking as many as 1,000 electrical fuse elements at once requires an instantaneous current of about 10 to 30 A. However, it is difficult with a conventional general-purpose tester to have a localized current flow of 10 to 30 A inside an LSI chip, and a dedicated tester will be needed. For example, in a case where there are 1,000 independent electrical fuse circuits and the electrical fuse elements are programmed one by one, there are required a large number of control terminals. Where there are four control terminals per circuit, for example, 4,000 control terminals are needed, and such a scheme cannot be implemented on system LSIs.

In view of such problems, United States Patent Application Publication No. 2006/0158920 discloses an electrical fuse circuit as follows.

FIG. 15 is a circuit diagram showing a configuration of the conventional electrical fuse circuit. Referring to FIG. 15, the electrical fuse circuit includes a plurality (n) of electrical fuse bit cells 500, and a programming shift register block 100 having a plurality (n) of stages. Each of the electrical fuse bit cells 500 includes one electrical fuse element 501. Where a program data signal FBmTi (i=1 to n) is at the high level (hereinafter referred to as the “H level”), the electrical fuse element 501 is broken while a program enable signal PBmTi (i=1 to n) from the programming shift register block 100 is at the H level. The programming shift register block 100 produces single-pulse program enable signals PBmTi (i=1 to n) that successively bring the first, second, . . . , stages to the H level, and outputs the produced signals to the first to n^{th} stages of electrical fuse bit cells 500, respectively.

The conventional electrical fuse circuit will now be described in greater detail. Referring to FIG. 15, the electrical fuse bit cell 500 includes the electrical fuse element 501, an NMOS transistor 502, and a 2-input AND circuit 503.

One end of the electrical fuse element 501 is connected to the power supply VDDHE (about 3.3 V) and the other end thereof is connected to the drain of the NMOS transistor 502. The NMOS transistor 502 is connected in series with the electrical fuse element 501, and the source thereof is connected to the ground terminal. The AND circuit 503 receives the program data signal FBmTi (i=1 to n) and the program enable signal PBmTi (i=1 to n), and outputs a program signal INmTi (i=1 to n) to the gate of the NMOS transistor 502.

The programming shift register block 100 includes n stages of shift registers (PSR) 101. The n stages of shift registers 101 are connected together in series, wherein each stage receives, as its input, the output from the preceding stage, with the first stage receiving a program control signal FPGI. A common program clock signal PCK is input to all of the first to n^{th} stages of shift registers 101. The program enable signals PBmTi (i=1 to n) output from the n shift registers 101 in the programming shift register block 100 are input to the first to n^{th} stages of electrical fuse bit cells 500, respectively.

FIG. 16 is a circuit diagram showing, in greater detail, the configuration of a single stage of shift register 101 in FIG. 15. Referring to FIG. 16, the shift register 101 includes two CMOS transmission gates 102 and 105, two inverter circuits 103 and 106, and two tri-state inverter circuits 104 and 107.

The first CMOS transmission gate 102 receives a program enable transmission signal PAmT(i−1), which is an output from the (i−1)^{th} stage, with the program clock signal PCK being input to a gate of a PMOS transistor, and an inverted signal NCK derived from the program clock signal PCK being input to a gate of an NMOS transistor. The program control signal FPGI is input to the first CMOS transmission gate 102 of the first stage.

The first inverter circuit 103 receives an output of the first CMOS transmission gate 102. The first tri-state inverter circuit 104 receives an output of the first inverter circuit 103, and uses the program clock signal PCK as its control signal (means “enable” when at the H level) to thereby give an output to a node between the first CMOS transmission gate 102 and the first inverter circuit 103.

The second CMOS transmission gate 105 receives an output of the first inverter circuit 103, with the inverted signal NCK derived from the program clock signal PCK being input to a gate of a PMOS transistor, and the program clock signal PCK being input to a gate of an NMOS transistor.

The second inverter circuit 106 receives an output of the second CMOS transmission gate 105 to output the program enable transmission signal PAmTi and the program enable signal PBmTi.

The second tri-state inverter circuit 107 receives an output of the second inverter circuit 106, and uses the inverted signal NCK derived from the program clock signal PCK as its control signal (means “enable” when at the H level) to thereby give an output to a node between the second CMOS transmission gate 105 and the second inverter circuit 106.

FIG. 17 is a waveform diagram showing an operation of the electrical fuse circuit of FIG. 15. First, the operation of the electrical fuse bit cell 500 of the i^{th} stage will be described.

In a programming operation, first, the program data signal FBmTi input to one input terminal of the AND circuit 503 is set to the H level or to the low level (hereinafter referred to as the “L level”). Specifically, the program data signal FBmTi is set to the H level when the electrical fuse element 501 should be broken, and to the L level when the electrical fuse element 501 should remain unbroken.

The program enable signal PBmTi is input to the other input terminal of the AND circuit 503. The electrical fuse bit cell 500 can break the electrical fuse element 501 only while the program enable signal PBmTi is at the H level. Specifically, where the program data signal FBmTi is at the H level, while the program enable signal PBmTi is at the H level, the program signal INmTi being the output of the AND circuit 503 goes to the H level to turn ON the NMOS transistor 502, thereby passing a current flow through the electrical fuse element 501, thus breaking the electrical fuse element 501. Where the program data signal FBmTi is at the L level, even if the program enable signal PBmTi goes to the H level, the output INmTi of the AND circuit 503 remains at the L level, and the NMOS transistor 502 remains OFF, whereby no current flows through the electrical fuse element 501, thus not breaking the electrical fuse element 501 (i.e., it remains unbroken).

The overall operation of the electrical fuse circuit will now be described. For example, in a case where the n electrical fuse bit cells 500 are to be programmed to 1, 0, . . . , 1, the signal levels of program data signals FBmT1, FBmT2, . . . , FBmTn are first set to H, L, . . . , H, respectively.

Then, the program control signal FPGI to be input to the first stage of the programming shift register block 100 is brought from the L level to the H level while keeping a sufficient setup time with respect to the rising edge of the program clock signal PCK. Since the program clock signal PCK is at the L level, the first CMOS transmission gate 102 (see FIG. 16) is ON, and the program control signal FPGI being at the H level is input to the shift register 101 of the first stage while the program clock signal PCK is at the L level.

When the program clock signal PCK rises from the L level to the H level, the first CMOS transmission gate 102 is turned OFF, and the output (the L level) of the first inverter circuit 103 is latched by the first inverter circuit 103 and the first tri-state inverter circuit 104 of the first stage and, at the same time, the second CMOS transmission gate 105 is turned ON, whereby a program enable signal PBmT1 and a program enable transmission signal PAmT1 of the first stage go to the H level. The program control signal FPGI falls to the L level while the program clock signal PCK is at the H level.

Then, when the program clock signal PCK falls from the H level to the L level, the first CMOS transmission gate 102 is again turned ON, whereby the program control signal FPGI being at the L level is input to the shift register 101 of the first stage and, at the same time, the second CMOS transmission gate 105 is turned OFF, and the output (the H level) of the second inverter circuit 106 is latched by the second inverter circuit 106 and the second tri-state inverter circuit 107 of the first stage, whereby the program enable signal PBmT1 and the program enable transmission signal PAmT1 of the first stage are held at the H level. While the program clock signal PCK is at the L level, the program enable transmission signal PAmT1 at the H level is input to the shift register 101 of the second stage.

Such an operation of the programming shift register block 100 successively produces the program enable signals PBmTi (i=1 to n) and the program enable transmission signals PAmTi (i=1 to n), each having a width equal to one cycle of the program clock signal PCK, as the program clock signal PCK periodically repeats its cycle.

When the program enable signal PBmTi input to the AND circuit 503 of the electrical fuse bit cell 500 (i=1 to n) goes to the H level, the electrical fuse bit cell 500 programs the electrical fuse element 501. Thus, the states of the program signals INmTi (i=1 to n) output from the AND circuits 503 are successively determined according to the program data signals (FBmT1, FBmT2, . . . , FBmTn)=(H, L, . . . , H), each at the rising edge of the program clock signal PCK.

In the example shown in FIG. 17, as the program enable signal PBmT1 of the first stage goes to the H level, the output INmT1 of the AND circuit 503 of the electrical fuse bit cell 500 of the first stage goes to the H level, and the NMOS transistor 502 is turned ON while a period corresponding to the pulse width of the program clock signal PCK to thereby break the electrical fuse element 501 of the first stage. In contrast, even when a program enable signal PBmT2 of the second stage goes to the H level, the output INmT2 of the AND circuit 503 of the electrical fuse bit cell 500 of the second stage remains at the L level, and the NMOS transistor 502 remains OFF, whereby the electrical fuse element 501 of the second stage is kept unbroken. Although not shown in the figure, the electrical fuse elements 501 are kept unbroken in the third to (n−1)^{th} stages, as in the second stage. As a program enable signal PBmTn of the last stage goes to the H level, the electrical fuse element 501 in the last stage is broken, as in the first stage.

As described above, the electrical fuse elements 501 are programmed one by one by using the single-pulse program enable signals PBmTi (i=1 to n) from the programming shift register block 100. Thus, a programming operation can be performed using a conventional general-purpose tester. Moreover, with the plurality of shift registers 101 being connected together in series, the total number of terminals can be reduced, thereby realizing an electrical fuse circuit that can be implemented on a system LSI.

With the conventional electrical fuse circuit, however, it is necessary to apply a voltage of 2.4 V or more across an electrical fuse element in order to pass a current of about 20 mA to break the electrical fuse element where the resistance of the electrical fuse element is 120 ohms. Accordingly, a 3.3 V-I/O NMOS transistor is used to apply a voltage of about 3 V across the electrical fuse element. Therefore, the conventional electrical fuse circuit requires a large 3.3-V I/O-type NMOS transistor whose gate width W is about 60 μm as a switch transistor for producing a required current flow for breaking the electrical fuse element. A 3.3-V I/O-type transistor is used also for the input to the gate of the NMOS transistor, and the area of the electrical fuse circuit is increased (the area of a 3.3-V I/O-type transistor is about twice as large as that of a 1.2-V logic-type transistor). If the production yield of memory cells decreases as the process rule further shrinks in the future, the number of electrical fuse elements to be provided may further increase, in which case the issue of the area of an electrical fuse circuit will be more serious.

In view of this, in a conventional electrical fuse circuit shown in FIG. 15, a 1.2-V logic-type transistor may be used as the NMOS transistor. However, with the conventional electrical fuse circuit, the same voltage (about 3.3 V) as the voltage applied to the top of the electrical fuse element is constantly applied also to the drain of the NMOS transistor while the gate voltage of the NMOS transistor is 0 V, hence a potential difference of about 3.3 V between the gate and the drain of the NMOS transistor, whereby the TDDB deterioration progresses.

On the other hand, the variety of applications of OTP memory devices have recently been extended. It is likely that OTP memory devices will in the future find applications such as, for example, system LSI chips having an ID function of storing system settings unique to each unit or a secure ID function of protecting information, semiconductor chips having a chip ID function of storing, for each chip, the lot number, the coordinates of the position of the chip, the pre-shipping inspection records, etc., so as to enable tracing (e.g., defect analysis), and IC tags used for tracking purposes such as logistics management and identification of baggage of airplane passengers.

For these applications, a medium-sized OTP memory of about 1 to 10 Kbits is used. Such an OTP memory is produced in large volumes, and should be sufficiently inexpensive to produce so as not to affect the cost of the product or service in which it is used.

Where an OTP memory is provided on a system LSI of a state-of-the-art process, the OTP memory should be able to be designed in a logic-based, timely manner, as with an SRAM. A non-volatile memory such as a flash memory requires an additional process, and the development thereof falls behind the state-of-the-art process by a few generations. In view of the timing of marketing, the manufacturing cost, etc., such a memory cannot meet demands in the market for systems using the state-of-the-art process, even though it is rewritable.

An electrical fuse circuit using silicide as described above may be used as an OTP memory capable of meeting such demands in the market. The electrical fuse circuit, which is used by breaking a silicide layer on a polysilicon layer, does not require an additional process as does a flash memory, but can be designed in a logic-based manner. However, a conventional electrical fuse circuit with a configuration as described above has a significant impact in terms of the chip area it occupies, and significantly affects the manufacturing cost.

### SUMMARY OF THE INVENTION

As described above, an I/O-type transistor having a large gate width is used in the prior art as a program driver for passing a current flow required for programming an electrical fuse element, thereby increasing the area of the electrical fuse circuit.

It is therefore a first object of the present invention to realize an electrical fuse circuit with which it is possible to reduce the total area.

Because of the principle of operation that an electrical fuse element is programmed by breaking the electrical fuse element by means of a current flow therethrough, it is necessary for an electrical fuse circuit that a current is reliably prevented from flowing through the electrical fuse element except when the electrical fuse element is programmed. In other words, it is important to ensure that the electrical fuse element can be broken reliably when being programmed while it is reliably prevented from being broken otherwise. A cause for an erroneous breaking of an electrical fuse element is an ESD surge current. Therefore, an electrical fuse circuit needs to have countermeasures against the erroneous breaking of electrical fuse elements upon ESD application. The provision of an anti-ESD circuit will increase the total area of the electrical fuse circuit. Therefore, it is important to provide the anti-ESD circuit with a small area.

It is therefore a second object of the present invention to provide a circuit for preventing an erroneous breaking of an electrical fuse so as to ensure the safety of an electrical fuse circuit, and to reduce the area of such a circuit.

In order to achieve the first object set forth above, the present invention is directed to an electrical fuse circuit, in which a fuse element is broken by a current flow therethrough, including a plurality of fuse bit cells, each including, in addition to an independent power supply switch circuit, a fuse element one end of which is connected to an output of the power supply switch circuit, and a first MOS transistor connected to the other end of the fuse element, wherein a gate oxide film thickness of a transistor of the fuse bit cell is equal to that of a logic transistor. Thus, it is possible to significantly reduce the area of the electrical fuse circuit.

In order to achieve the second object set forth above, the present invention is directed to an electrical fuse circuit, in which a fuse element is broken by a current flow therethrough, including a plurality of fuse bit cells, each including, in addition to an independent power supply switch circuit, a fuse element one end of which is connected to an output of the power supply switch circuit, and a first MOS transistor connected to the other end of the fuse element, wherein a diode is connected between a ground potential and the output of the power supply switch circuit, with an anode of the diode being connected to the ground potential and a cathode of the diode being connected to the output of the power supply switch circuit. Thus, it is possible to prevent an electrical fuse in an electrical fuse circuit from being broken erroneously, while reducing the total area.

### BRIEF DESCRIPTION OF THE DRAWINGS

FIG. 1 is a circuit diagram showing a configuration of an electrical fuse circuit according to an embodiment of the present invention.

FIG. 2 shows in detail a level shift circuit in the electrical fuse bit cell of FIG. 1.

FIG. 3 shows in detail a level shift circuit in the power supply switch circuit of FIG. 1.

FIG. 4 is a waveform diagram showing an operation of the electrical fuse circuit of FIG. 1.

FIG. 5 is a circuit diagram showing a configuration of an electrical fuse circuit according to another embodiment of the present invention.

FIG. 6 is a waveform diagram showing an operation of the electrical fuse circuit of FIG. 5.

FIG. 7 is a plan view showing an example of a system LSI including the electrical fuse circuit of FIG. 1 or 5.

FIG. 8 is a plan view showing another example of a system LSI including the electrical fuse circuit of FIG. 1 or 5.

FIG. 9 is a plan view showing the layout of a single I/O cell in a system LSI.

FIG. 10 is a circuit diagram of FIG. 9, showing a single I/O cell.

FIG. 11 is a plan view showing still another example of a system LSI including the electrical fuse circuit of FIG. 1 or 5.

FIG. 12 is a cross-sectional view taken along line XII-XII of FIG. 11.

FIG. 13 is a plan view showing still another example of a system LSI including the electrical fuse circuit of FIG. 1 or 5.

FIG. 14 is a cross-sectional view taken along line XIV-XIV of FIG. 13.

FIG. 15 is a circuit diagram showing a configuration of the conventional electrical fuse circuit.

FIG. 16 is a circuit diagram showing, in greater detail, the configuration of a single stage of shift register in FIG. 15.

FIG. 17 is a waveform diagram showing an operation of the electrical fuse circuit of FIG. 15.

### DETAILED DESCRIPTION OF THE INVENTION

Embodiments of the present invention will now be described with reference to the drawings. In a programming operation, an electrical fuse circuit programs each electrical fuse element by passing or not passing a current through the electrical fuse element so as to or not to break the electrical fuse element. A power supply VDD25 (about 2.5 V) is herein assumed as the power supply for programming electrical fuse elements. Note that the power supply for programming electrical fuse elements is not limited to the power supply VDD25 (about 2.5 V), but may be a power supply VDD33 (about 3.3 V).

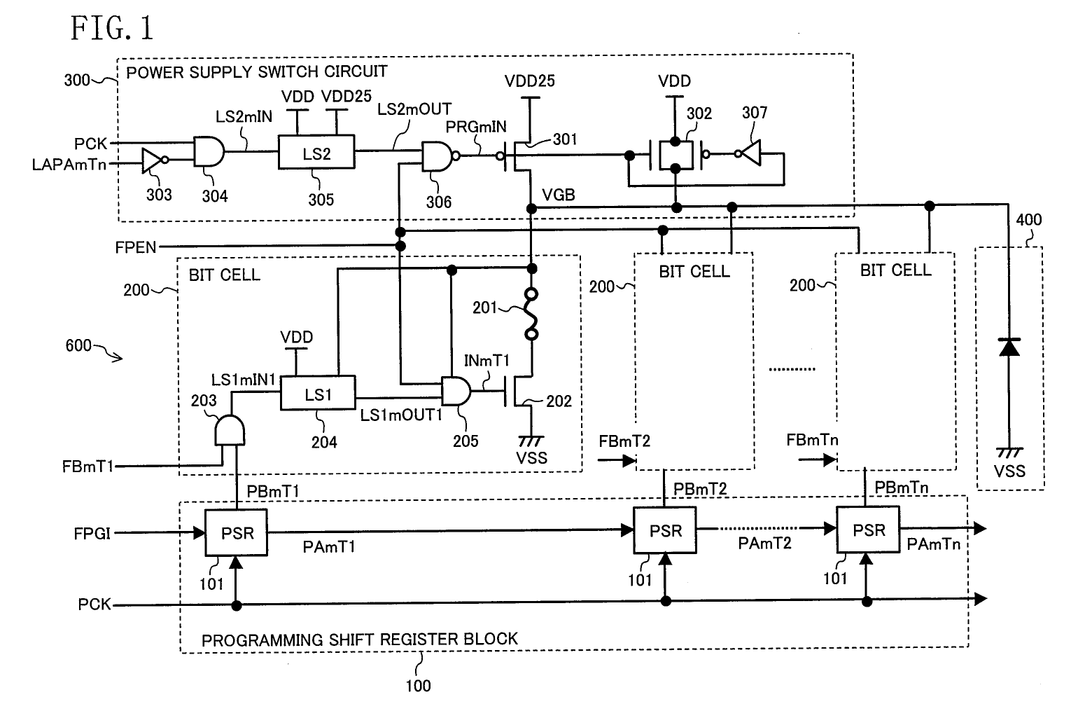

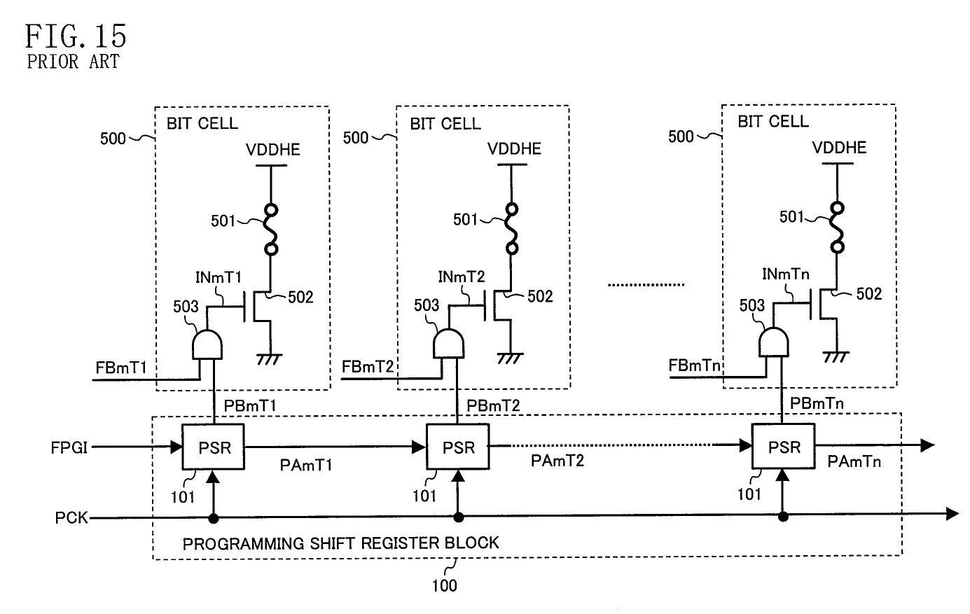

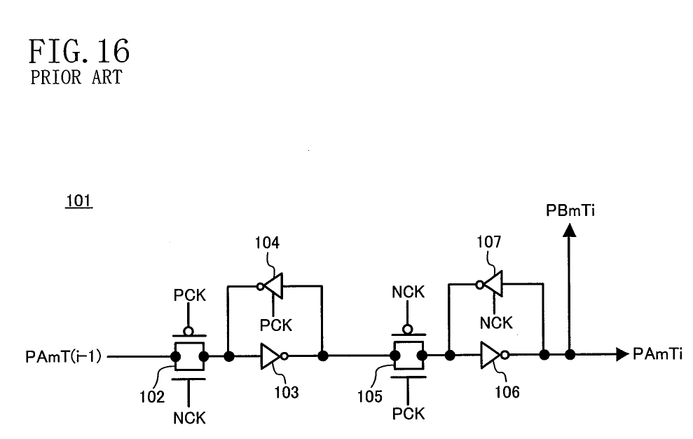

FIG. 1 is a circuit diagram showing a configuration of an electrical fuse circuit according to an embodiment of the present invention. Referring to FIG. 1, the electrical fuse circuit of the present invention includes a plurality (n) of electrical fuse bit cells 200, a programming shift register block 100 having a plurality (n) of stages, and a power supply switch circuit 300. The programming shift register block 100 and the plurality of electrical fuse bit cells 200 together form an electrical fuse section 600. The programming shift register block 100 is as described above with reference to FIGS. 15 and 16, and will not be further described below.

First, the electrical fuse bit cell 200 will be described. Referring to FIG. 1, the electrical fuse bit cell 200 includes an electrical fuse element 201, a 1.2-V logic-type NMOS transistor 202 being a first MOS transistor, first and second AND circuits 203 and 205, and a level shift circuit (LS1) 204. The 1.2-V logic-type transistor 202 is not limited to a 1.2-V transistor, but the same effect will be achieved with any other appropriate logic-type transistor such as a 1.0-V transistor.

The electrical fuse element 201 includes a polysilicon layer and a silicide layer formed on the polysilicon layer, wherein the electrical fuse element 201 has a low resistance when the silicide layer is unbroken and has a high resistance when the silicide layer is broken by a current flow therethrough. One end of the electrical fuse element 201 is connected to the drain of the NMOS transistor 202. The NMOS transistor 202 is connected in series with the electrical fuse element 201, and the source thereof is connected to the ground potential (VSS). The output signal line (VGB) of the power supply switch circuit 300 is connected to the other end of the electrical fuse element 201.

The first AND circuit 203 is made of 1.2-V logic-type transistors, and uses a 1.2-V power supply (VDD) as its power supply. The 2-input AND circuit 203 receives the program data signal FBmTi (i=1 to n) and the program enable signal PBmTi (i=1 to n), and outputs a signal LS1mINi (i=1 to n) to the level shift circuit 204. The program data signal FBmTi is set to the H level (the VDD level) when breaking the electrical fuse element 201, and to the L level when keeping the electrical fuse element 201 unbroken. Therefore, when breaking the electrical fuse element 201, the output LS1mINi of the first AND circuit 203 goes to the H level (the VDD level) while the program enable signal PBmTi is at the H level (the VDD level). When not breaking the electrical fuse element 201, the output LS1mINi is at the L level, irrespective of the program enable signal PBmTi.

The level shift circuit 204 receiving the output LS1mINi (i=1 to n) of the first AND circuit 203 uses the power supply VDD and the signal VGB as its power supplies to convert the VDD level to the voltage level of the signal VGB. The output LS1mOUTi (i=1 to n) of the level shift circuit 204 is at the voltage level of the signal VGB while the program enable signal PBmTi is at the H level when breaking the electrical fuse element 201, and is at the L level when not breaking the electrical fuse element 201.

The second AND circuit 205 is made of 2.5-V I/O-type transistors having a thick gate oxide film, and uses the signal VGB as its power supply. The 2-input AND circuit 205 receives the output LS1mOUTi of the level shift circuit 204 and a fuse program enable signal FPEN, and outputs the program signal INmTi (i=1 to n) to the gate of the NMOS transistor 202.

The fuse program enable signal FPEN is a control terminal signal, independent of the power supply VDD25 of the electrical fuse circuit, and is set to the VDD25 level in a programming operation and fixed to the L level in a non-programming operation. The power supply VDD25 (about 2.5 V) has a greater power supply voltage than the power supply VDD (about 1.2 V). As will be described later, the signal VGB transitions between the VDD level and the VDD25 level in synchronism with the clock cycle of the program clock signal PCK. Therefore, when breaking the electrical fuse element 201, the program signal INmTi transitions to the VDD25 level while the program enable signal PBmTi is at the H level and the signal VGB is at the VDD25 level.

As described above, the electrical fuse bit cell 200 includes the level shift circuit 204 for voltage conversion along the signal line that connects to the gate of the NMOS transistor 202. The level shift circuit 204 performs a voltage conversion only when breaking the electrical fuse element 201, to thereby produce the signal LS1mOUTi having the voltage level of the signal VGB. In a programming operation, the fuse program enable signal FPEN is set to the H level (the VDD25 level). Therefore, while the signal LS1mOUTi is at the VDD25 level (in a programming operation), the second AND circuit 205 produces a program signal INmTi at the VDD25 level and applies the produced signal to the gate of the NMOS transistor 202 to thereby turn ON the NMOS transistor 202. Thus, by setting the gate voltage to the VDD25 level, it is possible even with a 1.2-V logic-type NMOS transistor to pass a current necessary for breaking the electrical fuse element 201 when the signal VGB applied to the top of the electrical fuse element 201 is at the VDD25 level.

Next, the power supply switch circuit 300 will be described. The power supply switch circuit 300 includes a 2.5-V I/O-type PMOS transistor 301 that is connected in series with each electrical fuse element 201, whereby the signal VGB at the VDD25 level is applied from the PMOS transistor 301 commonly to the electrical fuse bit cells 200 each time the program clock signal PCK rises from the L level to the H level. A plurality of electrical fuse bit cells 200 are connected to the output signal VGB of the power supply switch circuit 300.

Referring to FIG. 1, the power supply switch circuit 300 includes the 2.5-V I/O-type PMOS transistor 301, a 2.5-V I/O-type CMOS transmission gate 302, inverter circuits 303 and 307, an AND circuit 304, a level shift circuit (LS2) 305, and an NAND circuit 306.

The source of the PMOS transistor 301 is connected to the power supply VDD25, the gate thereof receives a program enable switch signal PRGmIN, and the drain thereof is connected to the electrical fuse elements 201. One of the source and the drain of the CMOS transmission gate 302, which is connected in parallel to the PMOS transistor 301, is connected to the power supply VDD, the gate thereof receives the program enable switch signal PRGmIN, and the other one of the source and the drain thereof is connected to the electrical fuse elements 201. With the PMOS transistor 301 and the CMOS transmission gate 302, either VDD25 or VDD can selectively be output from the output VGB of the power supply switch circuit 300.

Thus, the program enable switch signal PRGmIN is commonly input to the PMOS transistor 301 and the CMOS transmission gate 302, and when the signal PRGmIN goes to the H level (the VDD25 level), the PMOS transistor 301 is turned OFF and the CMOS transmission gate 302 is turned ON, whereby the output signal VGB of the power supply switch circuit 300 is at the VDD level. When the program enable switch signal PRGmIN goes to the L level, the PMOS transistor 301 is turned ON and the CMOS transmission gate 302 is turned OFF, whereby the output signal VGB of the power supply switch circuit 300 is at the VDD25 level. Therefore, a voltage of the VDD25 level is applied to the electrical fuse element 201 of each electrical fuse bit cell 200 in a programming operation, and a voltage of the VDD level is applied to the electrical fuse element 201 of each electrical fuse bit cell 200 in a non-programming operation.

Taking the design margin of the power supply VDD into consideration, it is possible to stably pass and output VDD by using the CMOS transmission gate 302 as a transistor that is connected to the power supply VDD. Thus, it is possible to realize a stable output operation of the power supply switch circuit 300.

The inverter circuit 303 receives a signal LAPAmTn. The signal LAPAmTn is produced by latching the falling edge of the program enable transmission signal PAmTn, being the output of the last stage of the programming shift register block 100.

The AND circuit 304 is made of 1.2-V logic-type transistors, and uses VDD as its power supply. The 2-input AND circuit 304 receives an output of the inverter circuit 303 and the program clock signal PCK, and outputs a signal LS2mIN to the level shift circuit 305. The level shift circuit 305, receiving an output LS2mIN of the AND circuit 304, uses the power supplies VDD and VDD25 as is power supplies to convert the VDD level to the VDD25 level.

The NAND circuit 306 is made of 2.5-V I/O-type transistors, and uses the power supply VDD25 as its power supply. The 2-input NAND circuit 306 receives an output LS2mOUT of the level shift circuit 305 and the fuse program enable signal FPEN to produce the program enable switch signal PRGmIN and output the produced signal commonly to the gates of the PMOS transistor 301 and the CMOS transmission gate 302.

With such a configuration, the program enable switch signal PRGmIN is produced, which repeats its cycle in synchronism with the clock pulses of the program clock signal PCK, inside the power supply switch circuit 300. Specifically, the program enable switch signal PRGmIN transitions to the L level and the output VGB of the power supply switch circuit 300 is brought to the VDD25 level, each time the program clock signal PCK rises from the L level to the H level. Similarly, the program enable switch signal PRGmIN transitions to the H level (the VDD25 level) and the output VGB of the power supply switch circuit 300 is brought to the VDD level, each time the program clock signal PCK falls from the H level to the L level.

Thus, in synchronism with the program clock signal PCK, the power supply switch circuit 300 alternately turns ON the PMOS transistor 301 and the CMOS transmission gate 302, whereby the output VGB transitions between the VDD25 level and the VDD level.

On the other hand, as the program clock signal PCK periodically repeats its cycle, the programming shift register block 100 successively outputs one-shot pulse signals each having a pulse width equal to one cycle of the program clock signal PCK (i.e., the program enable signals PBmTi (i=1 to n)) to the first to n^{th} stages of electrical fuse bit cells 200, respectively.

Therefore, where the program data signal FBmTi is at the H level, the electrical fuse bit cell 200 can apply the program signal INmTi at the VDD25 level to the gate of the NMOS transistor 202 to thereby break the electrical fuse element 201 while the program enable signal PBmTi is at the H level and the output signal VGB of the power supply switch circuit 300 is at the VDD25 level.

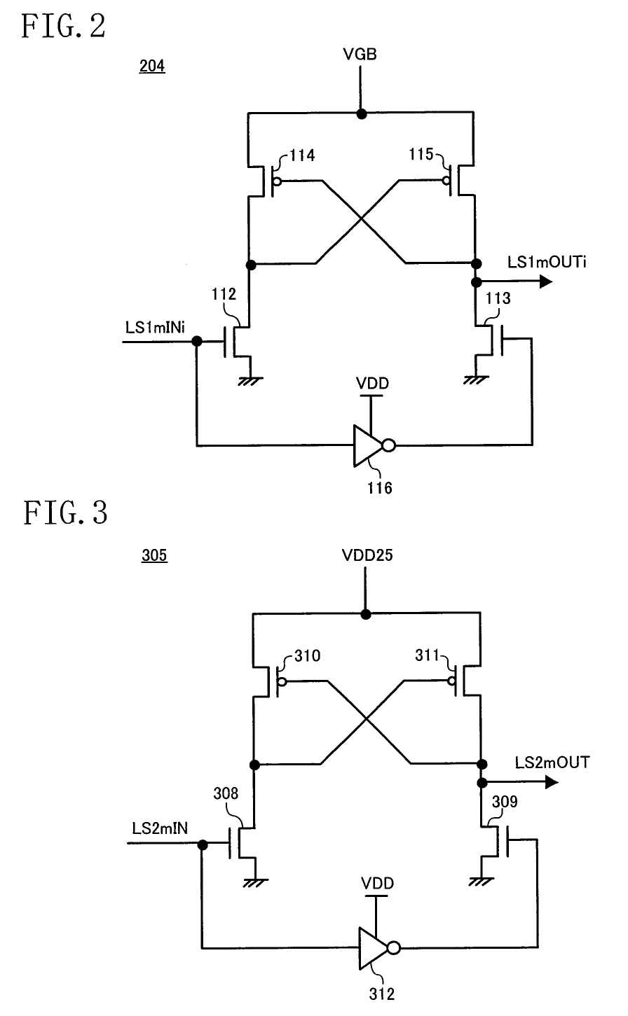

FIG. 2 shows in detail the level shift circuit 204 in the electrical fuse bit cell 200 of FIG. 1. The level shift circuit 204 includes first and second NMOS transistors 112 and 113, first and second PMOS transistors 114 and 115 each being a 1.2 V logic-type transistor, and an inverter circuit 116 made of 1.2 V logic-type transistors.

The gate of the first NMOS transistor 112 receives the output LS1mINi of the first AND circuit 203. The power supply of the inverter circuit 116 is VDD. The drain of the second NMOS transistor 113 is the output terminal LS1mOUTi of the level shift circuit 204.

The gate of the first PMOS transistor 114 is connected to the drain of the second NMOS transistor 113 (the output terminal LS1mOUTi of the level shift circuit), the drain thereof is connected to the drain of the first NMOS transistor 112, and the source thereof receives the output signal VGB of the power supply switch circuit 300. The gate of the second PMOS transistor 115 is connected to the drain of the first PMOS transistor 114, the drain thereof is connected to the drain of the second NMOS transistor 113 (the output terminal LS1mOUTi of the level shift circuit), and the source thereof receives the output signal VGB of the power supply switch circuit 300.

With such a configuration, when the signal LS1mNi being the input signal of the level shift circuit 204 is at the L level, the first NMOS transistor 112 is OFF, the second NMOS transistor 113 is ON, the first PMOS transistor 114 is ON and the second PMOS transistor 115 is OFF, whereby the signal level of the output LS1mOUTi is at the L level. Where the input signal LS1mNi is at the H level (the VDD level), the first NMOS transistor 112 is ON, the second NMOS transistor 113 is OFF, the first PMOS transistor 114 is OFF, and the second PMOS transistor 115 is ON, whereby the signal level of the output LS1mOUTi is at the voltage level of the signal VGB.

In the present embodiment, a logic-type transistor is used for each circuit element preceding the level shift circuit 204, thereby realizing a reduction in the total area. Moreover, the level shift circuit 204 itself is made of logic-type transistors, thereby realizing a further reduction in the total area.

By using the signal VGB as the high voltage-side power supply of the level shift circuit 204 as shown in FIG. 2 so that a voltage of the VDD25 level and a voltage of the VDD level are supplied alternately, it is possible to reduce the stress on the gate oxide films of the transistors 112 to 115 of the level shift circuit 204, thereby slowing the progress of the TDDB deterioration.

FIG. 3 shows in detail the level shift circuit 305 in the power supply switch circuit 300 of FIG. 1. The level shift circuit 305 includes first and second NMOS transistors 308 and 309, first and second PMOS transistors 310 and 311, each being a 2.5 V I/O transistor, and an inverter circuit 312 made of 1.2-V logic-type transistors. The arrangement is similar to that of the level shift circuit 204 described above. Note however that the power supply VDD25 is connected to the source of the first and second PMOS transistors 310 and 311. The operation is similar to that of the level shift circuit 204 described above.

Thus, by inserting the level shift circuit 305 along the signal line that is connected to the gate of the PMOS transistor 301 and the CMOS transmission gate 302 of the power supply switch circuit 300, the ON/OFF of the PMOS transistor 301 and the CMOS transmission gate 302 can be controlled by using the clock signal PCK without having to separately provide an external control terminal. Thus, it is possible to use logic-type transistors for all circuit elements preceding the level shift circuit 305, thereby realizing a significant reduction in the total area.

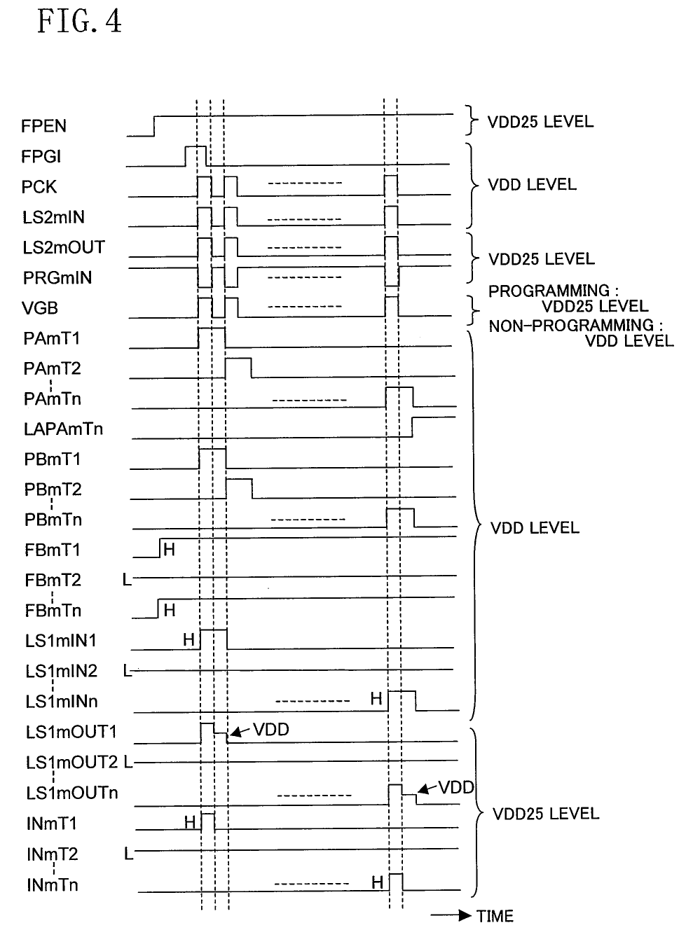

FIG. 4 is a waveform diagram showing an operation of the electrical fuse circuit of FIG. 1. The operation of an electrical fuse circuit in which a plurality of electrical fuse bit cells 200 are connected to the output signal terminal of the power supply switch circuit 300 will now be described with reference to FIG. 4.

Referring to FIG. 4, the fuse program enable signal FPEN is fixed to the L level before the start of a programming operation. Therefore, before a programming operation, the output INmTi of the second AND circuit 205 of the electrical fuse bit cell 200 is fixed to the L level, whereby the NMOS transistor 202 is OFF (disabled). Moreover, the output PRGmIN of the NAND circuit 306 of the power supply switch circuit 300 is fixed to the H level, whereby the PMOS transistor 301 is OFF (disabled) and the output VGB of the power supply switch circuit 300 is at the VDD level.

When a programming operation is started, the fuse program enable signal FPEN is transitioned from the L level to the H level which is exemplarily a voltage of 2.5 V, and is input independently of the power supply VDD25. Then, it is possible to start a programming operation of the electrical fuse bit cells 200. Thus, the fuse program enable signal FPEN brings the PMOS transistor 301 and the CMOS transmission gate 302 to a programming enabled state at the time of a programming operation.

As described above, a control terminal independent of the power supply is provided and set to the L level before a programming operation, thus forcibly turning OFF the NMOS transistors 202 of the electrical fuse bit cells 200 and the PMOS transistor 301 of the power supply switch circuit 300. Therefore, it is possible to prevent an erroneous breaking of the electrical fuse element 201 due to an erroneous operation of the level shift circuits 204 and 305 at the power-on of the power supply, for example.

While the program clock signal PCK is at the L level, the output LS2mIN of the AND circuit 304 of the power supply switch circuit 300 is at the L level (LAPAmTn is initially at the L level), and the output LS2mOUT of the level shift circuit 305 is also at the L level. Therefore, the output PRGmIN of the NAND circuit 306 is at the H level (the VDD25 level), thus turning the PMOS transistor 301 OFF and the CMOS transmission gate 302 ON, whereby the output VGB of the power supply switch circuit 300 is at the VDD level (about 1.2 V).

While the program clock signal PCK is at the H level, the output LS2mIN of the AND circuit 304 of the power supply switch circuit 300 is at the H level (the VDD level), and the signal LS2mOUT at the H level (the VDD25 level) is output from the level shift circuit 305. With the signal LS2mOUT being at the H level (the VDD25 level) and the signal FPEN being at the H level (the VDD25 level), the PMOS transistor 301 is turned ON, and the CMOS transmission gate 302 is turned OFF. Therefore, the output signal VGB of the power supply switch circuit 300 is at the VDD25 level (about 2.5 V).

Therefore, in synchronism with the clock cycle of the program clock signal PCK, the signal VGB is at the VDD level while the program clock signal PCK is at the L level, and is at the VDD25 level while the program clock signal PCK is at the H level.

The operation of the electrical fuse circuit will now be described, with respect to that of the i^{th} stage. When programming the electrical fuse circuit, the program data signal FBmTi is set to the H level when breaking the electrical fuse element 201 of the i^{th} stage and set to the L level when not breaking the electrical fuse element 201 of the i^{th} stage. The electrical fuse bit cell 200 programs the electrical fuse element 201 only when the program enable signal PBmTi is at the H level.

Specifically, the shift register 101 of the programming shift register block 100 is controlled by a 1.2-V logic-type power supply VDD, and in a case where the program data signal FBmTi is at the H level (the VDD level), a signal at the VDD level is input to the level shift circuit 204 while the program enable signal PBmTi is at the H level. The level shift circuit 204 converts the VDD level to the VDD25 level while the signal VGB is at the VDD25 level. The output INmTi of the second AND circuit 205, receiving the signal LS1mOUTi at the VDD25 level and the fuse program enable signal FPEN at the VDD25 level, goes to the VDD25 level (the H level), thereby turning ON the NMOS transistor 202. Then, since the signal VGB is at the VDD25 level, there is a current flow required for breaking the electrical fuse element 201, thereby breaking the electrical fuse element 201.

In a case where the program data signal FBmTi is at the L level, even if the program enable signal PBmTi is at the H level, the output LS1mINi of the first AND circuit 203 is at the L level, and the output LS1mOUTi of the level shift circuit 204 is also at the L level. Therefore, the NMOS transistor 202 is OFF, and there is no current flow through the electrical fuse element 201, thereby not breaking the electrical fuse element 201.

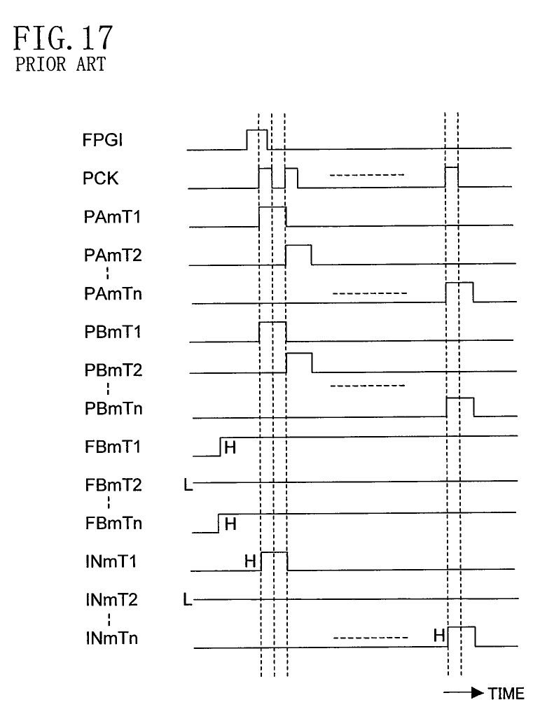

The overall operation of the electrical fuse circuit will now be described. The operation of the programming shift register block 100 is as described above with reference to FIGS. 15 to 17, and will not be further described below.

For example, where the n electrical fuse bit cells 200 are to be programmed to 1, 0, . . . , 1, the signal levels of the program data signal FBmT1, FBmT2, . . . , FBmTn are first set to H, L, . . . , H, respectively.

Then, after the fuse program enable signal FPEN is transitioned to the H level, the program control signal FPGI to be input to the first stage of the programming shift register block 100 is raised from the L level to the H level while keeping a sufficient setup time with respect to the rising edge of the program clock signal PCK. The program control signal FPGI at the H level is input to the shift register 101 of the first stage while the program clock signal PCK is at the L level.

The programming shift register block 100 successively produces the program enable signals PBmTi (i=1 to n) and the program enable transmission signals PAmTi (i=1 to n), each having a width equal to one cycle of the program clock signal PCK, as the program clock signal PCK periodically repeats its cycle.

As the program enable signal PBmTi (i=1 to n) of the electrical fuse bit cell 200 goes to the H level, the electrical fuse bit cell 200 programs the electrical fuse element 201. Specifically, the states of the signals LS1mINi (i=1 to n) output from the first AND circuits 203 are successively determined according to the program data signals FBmT1, FBmT2, . . . , FBmTn (=H, L, . . . , H), each at a rising edge of the program clock signal PCK.

In the example shown in FIG. 4, the output LS1mINi of the first AND circuit 203 of the electrical fuse bit cell 200 of the first stage is at the H level while the program enable signal PBmT1 of the first stage is at the H level, and the signal LS1mOUT1, which has been converted by the level shift circuit 204 to the voltage level of the signal VGB, is input to the second AND circuit 205, whereby the program signal INmT1 is at the H level while the program clock signal PCK is at the H level, thus breaking the electrical fuse element 201 of the first stage.

Even when the program enable signal PBmT2 of the second stage goes to the H level, the output LS1mIN2 of the first AND circuit 203 of the electrical fuse bit cell 200 of the second stage stays at the L level, and the signal LS1mOUT2 at the L level and the program signal INmT2 at the L level are output from the level shift circuit 204 and from the second AND circuit 205, respectively, thereby turning OFF the NMOS transistor 202, and thus not breaking the electrical fuse element 201 of the second stage. This similarly applies to the third and subsequent stages.

Upon completion of programming of the electrical fuse element 201 of the n^{th} stage, the output PAmTn of the programming shift register block 100 transitions from the H level to the L level. As the signal LAPAmTn latched at the H level (the VDD level) is input to the power supply switch circuit 300 at this falling edge, the output of the AND circuit 304 of the power supply switch circuit 300 transitions to the L level, whereby the output LS2mOUT of the level shift circuit 305 also transitions to the L level, irrespective of the program clock signal PCK. Thus, after the completion of a programming operation, the electrical fuse elements can no longer be programmed.

As described above, with the embodiment of FIG. 1, a plurality of electrical fuse elements 201 can be programmed. Moreover, since a high voltage of VDD25 is not constantly applied to the NMOS transistor 202 for passing a current for breaking the electrical fuse element 201, a transistor having a low withstand voltage (e.g., a 1.2-V logic-type transistor) can be used as the NMOS transistor 202. Thus, 1.2-V logic-type transistors can be used as all transistors except for the second AND circuit 205 of the electrical fuse bit cell 200, whereby it is possible to significantly reduce the total area as compared with a case where 2.5-V I/O-type transistors are used. Moreover, by using a common power supply switch circuit 300 for a plurality of electrical fuse bit cells 200, it is possible to reduce the total area of the electrical fuse circuit.

A cause of an erroneous breaking of the electrical fuse element 201 of FIG. 1 is an ESD surge current. For example, referring to FIG. 1, if a parasitic diode existing between the P-type silicon substrate of the NMOS transistor 202, which is a program driver for each electrical fuse bit cell 200, and the N-type diffusion layer being the drain is turned ON, a surge current flows through the electrical fuse element 201 to thereby erroneously break the electrical fuse element 201. Therefore, in FIG. 1, a diode 400 is inserted between the output signal VGB of the power supply switch circuit 300 and the ground potential VSS, as a countermeasure against the erroneous breaking of the electrical fuse element 201 upon ESD application.

Specifically, referring to FIG. 1, the diode 400 is inserted between the output signal VGB of the power supply switch circuit 300 and the ground potential VSS, with the anode of the diode 400 being connected to the ground potential VSS, and the cathode thereof being connected to the output signal VGB of the power supply switch circuit 300. Upon ESD application to the ground potential VSS, the ESD surge current is shunted to the inserted diode 400, thereby preventing the surge current from flowing into the electrical fuse elements 201 of the electrical fuse bit cells 200. Thus, with the provision of the diode 400, it is possible to prevent the electrical fuse element 201 of each electrical fuse bit cell 200 from being erroneously broken by ESD.

A countermeasure against a surge current upon ESD application to the ground potential may be to insert a diode 400 between the ground potential VSS and the power supply VDD25 and another diode 400 between the ground potential VSS and the power supply VDD. However, as compared with a case where two diodes 400 are inserted, one between the ground potential VSS and the power supply VDD25 and another between the ground potential VSS and the power supply VDD, it is possible to reduce the number of diodes and to reduce the total area of diode inserted as an ESD countermeasure with a configuration as shown in FIG. 1 where the diode 400 is inserted between the output signal VGB of the power supply switch circuit 300 and the ground potential VSS.

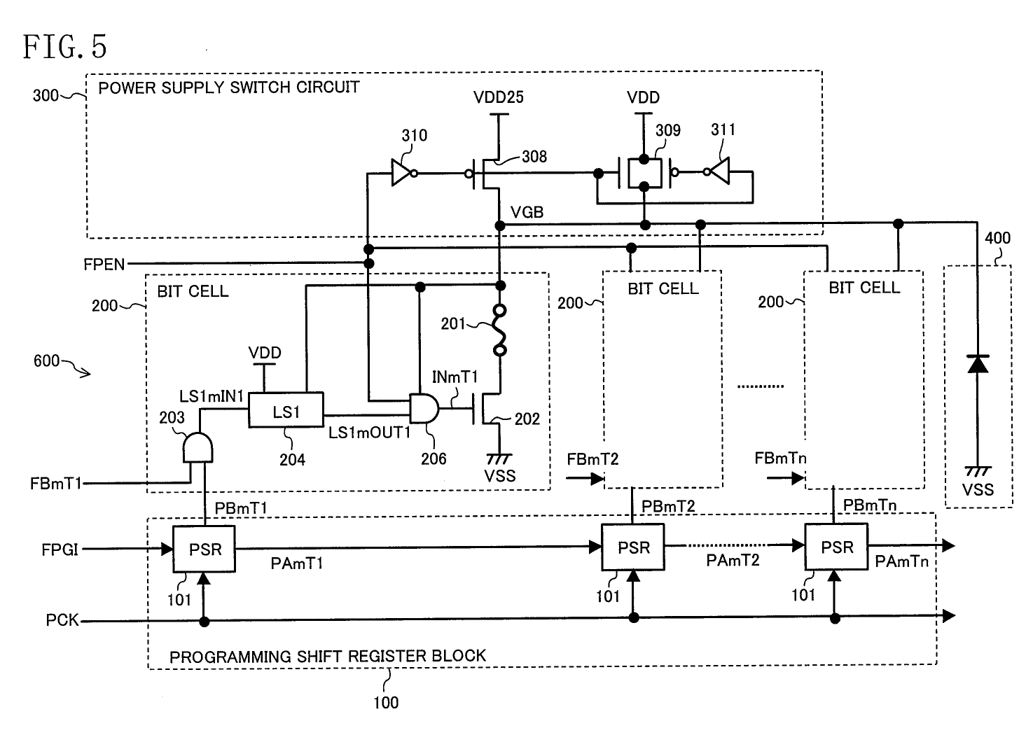

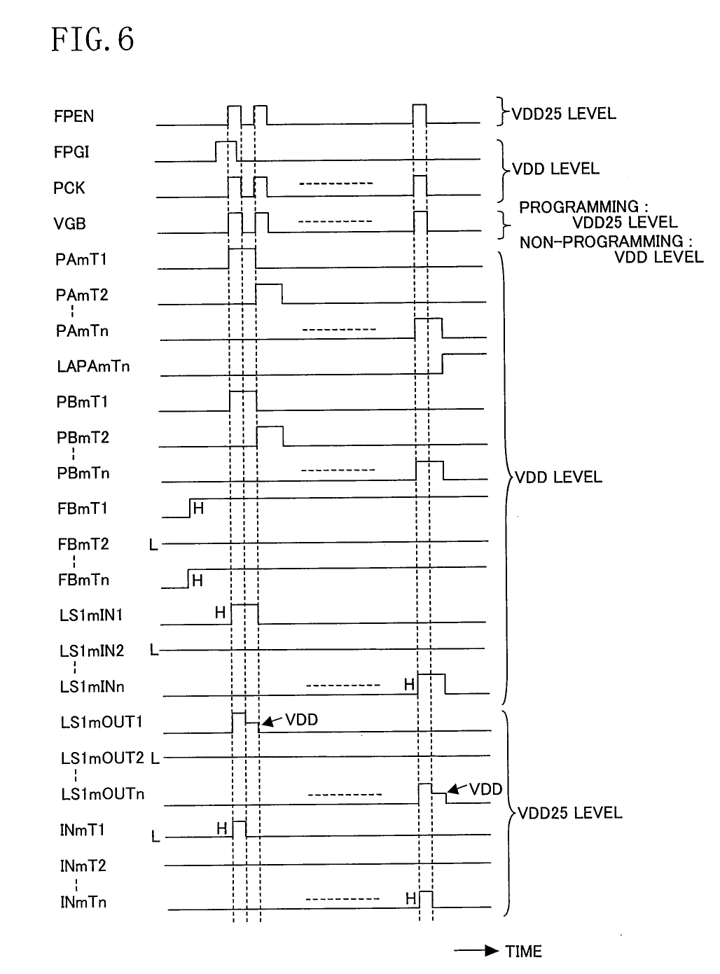

FIG. 5 is a circuit diagram showing a configuration of an electrical fuse circuit according to another embodiment of the present invention. FIG. 6 is a waveform diagram showing an operation of the electrical fuse circuit of FIG. 5.

Similar to the embodiment of FIG. 1, the electrical fuse circuit of the embodiment of FIG. 5 includes a plurality (n) of electrical fuse bit cells 200, a programming shift register block 100 having a plurality (n) of stages, and a power supply switch circuit 300. The components are the same as those of the embodiment of FIG. 1, except for the power supply switch circuit 300.

The power supply switch circuit 300 of the present embodiment will now be described. A signal that repeats its cycle in synchronism with the program clock signal PCK in a programming operation is used as the fuse program enable signal FPEN. Specifically, the input signal is the signal FPEN, which is at the H level (the VDD25 level) while the program clock signal PCK is at the H level, and at the L level while the program clock signal PCK is at the L level. The power supply switch circuit 300 includes a 2.5-V I/O-type PMOS transistor 308, a 2.5-V I/O-type CMOS transmission gate 309, and 2.5-V I/O-type inverter circuits 310 and 311. Taking the design margin of the power supply VDD into consideration, it is possible to stably pass and output VDD by using the CMOS transmission gate 309 as transistors that are connected to the power supply VDD. Thus, it is possible to realize a stable output operation of the power supply switch circuit 300.

With the circuit configuration shown in FIG. 5, the output VGB of the power supply switch circuit 300 goes to the VDD25 level each time the fuse program enable signal FPEN, which repeats its cycle in synchronism with the cycle of the program clock signal PCK, rises from the L level to the H level. Each time the fuse program enable signal FPEN falls from the H level to the L level, the output VGB of the power supply switch circuit 300 goes to the VDD level.

The operation of the electrical fuse bit cell 200 will now be described. The electrical fuse bit cell 200 differs from that of the embodiment of FIG. 1 only in that the fuse program enable signal FPEN, which is input to one terminal of a second AND circuit 206, is a signal that repeats its cycle. In a case where the program data signal FBmTi is at the H level, the output INmTi of the second AND circuit 206 goes to the VDD25 level to thereby turn ON the NMOS transistor 202, while the program enable signal PBmTi is at the H level and the signal VGB is at the VDD25 level. Then, since the signal VGB is at the VDD25 level, there is a current flow required for breaking the electrical fuse element 201, thereby breaking the electrical fuse element 201. In a case where the program data signal FBmTi is at the L level, the electrical fuse element 201 is not broken.

As described above, the output VGB of the power supply switch circuit 300 has the same waveform as that of the embodiment of FIG. 1, and the electrical fuse bit cell 200 operates as described in the embodiment of FIG. 1, whereby the overall operation of the electrical fuse circuit is similar to that of the embodiment of FIG. 1.

Thus, the electrical fuse circuit of the embodiment of FIG. 5 realizes a similar function to that of the electrical fuse circuit of the embodiment of FIG. 1, with the same input terminal configuration. Moreover, since the PMOS transistor 308 is turned ON/OFF according to the program enable signal FPEN independent of the power supply, whereby it is possible to eliminate the need for the level shift circuit 305 and the preceding control circuits 303 and 304, as compare with the embodiment of FIG. 1, thus realizing a further reduction in the total area.

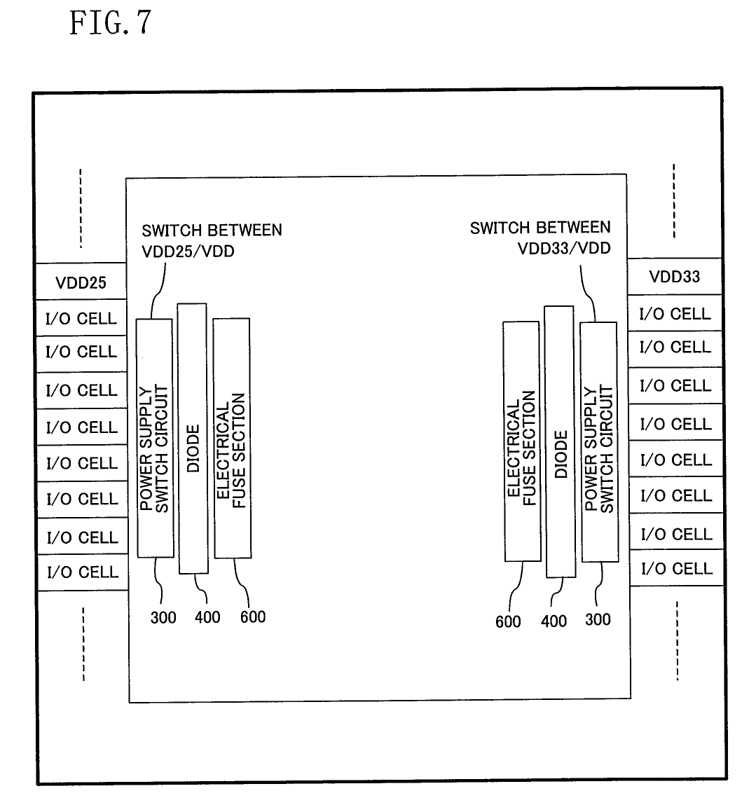

FIG. 7 is a plan view showing an example of a system LSI including the electrical fuse circuit of FIG. 1 or 5. Illustrated herein is an SoC (System on Chip) including an electrical fuse circuit using two power supplies of the I/O power supply VDD25 and the power supply VDD, and an electrical fuse circuit using two power supplies of the I/O power supply VDD33 and the power supply VDD. The power supply VDD25 (about 2.5 V) is smaller than the power supply VDD33 (about 3.3 V).

Referring to FIG. 7, an I/O cell region extends along the periphery of the system LSI, and the system LSI includes the power supply switch circuit 300, the diode 400 and the electrical fuse section 600 (including a plurality of electrical fuse bit cells 200 and the programming shift register block 100) arranged in this order from the I/O cell region toward the center of the system LSI. With such an arrangement of the power supply switch circuit 300, the diode 400 and the electrical fuse section 600, when an ESD surge current is applied to the VSS terminal in the I/O cell region, the surge current can be absorbed by the diode 400, which precedes the electrical fuse section 600. Thus, it is possible to make effective use of the diode 400, and to prevent electrical fuse elements from being erroneously broken.

In a case where a plurality of I/O power supply voltages (VDD33, VDD25, etc.) are used in a system LSI, circuits using the power supply VDD33 may be arranged together (thereby forming what is hereinafter referred to as a “VDD33 power supply island”) and those using the power supply VDD25 may be arranged together (forming a “VDD25 power supply island”) in the system LSI. If an electrical fuse circuit is compatible only with one I/O power supply, e.g., the power supply VDD25, there will be limitations on the arrangement of the electrical fuse circuit in the system LSI. Therefore, it is preferred that an electrical fuse circuit can be programmed by using different I/O power supplies.

In view of this, transistors manufactured according to the withstand voltage of the highest I/O power supply voltage among a plurality of I/O power supplies in the system LSI may be used for all the transistors of the PMOS transistor 308, the CMOS transmission gate 309 and the inverter circuits 310 and 311 of the power supply switch circuit 300, in FIG. 5, for example. Specifically, the gate length of all the transistors of the power supply switch circuit 300 may be set to a length determined according to the withstand voltage of the highest I/O power supply voltage among a plurality of I/O power supplies in the system LSI. Moreover, the gate width of the PMOS transistor 308 and the CMOS transmission gate 309 of the power supply switch circuit 300 may be set to a length determined according to the current driving capability obtained when using the lowest I/O power supply voltage among a plurality of I/O power supplies in the system LSI. Then, the electrical fuse circuit can be operated by using different I/O power supply voltages in the system LSI, whereby it is possible to eliminate the limitations on the arrangement in the system LSI.

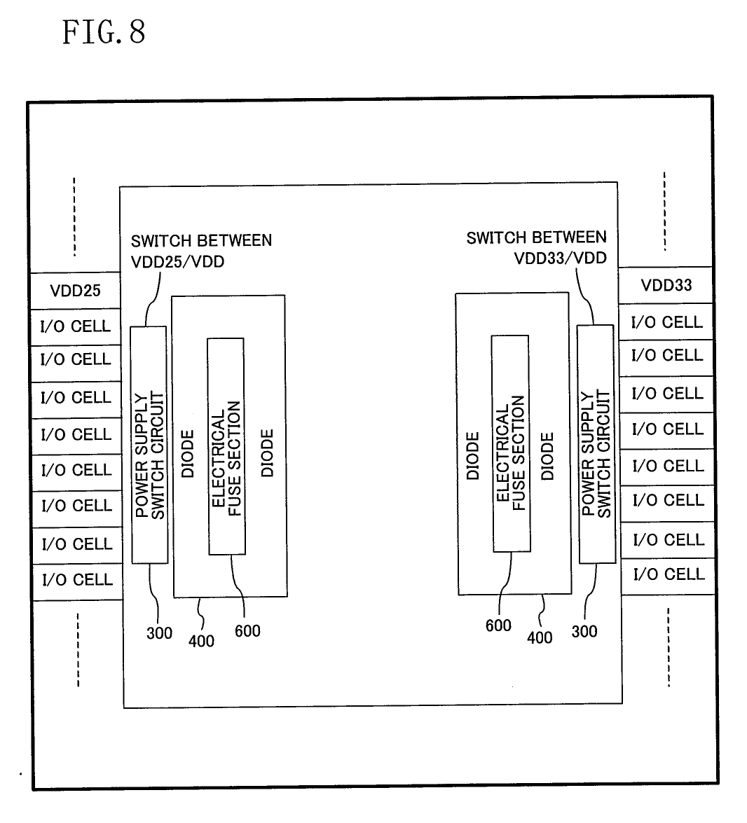

FIG. 8 is a plan view showing another example of a system LSI including the electrical fuse circuit of FIG. 1 or 5. The diode 400 is provided around the electrical fuse section 600 including a plurality of electrical fuse bit cells 200. As a result, even if an ESD surge current is applied to any VSS terminal in the I/O cell region, the surge current can be absorbed by the diode 400 even more efficiently, thereby preventing electrical fuse elements from being erroneously broken.

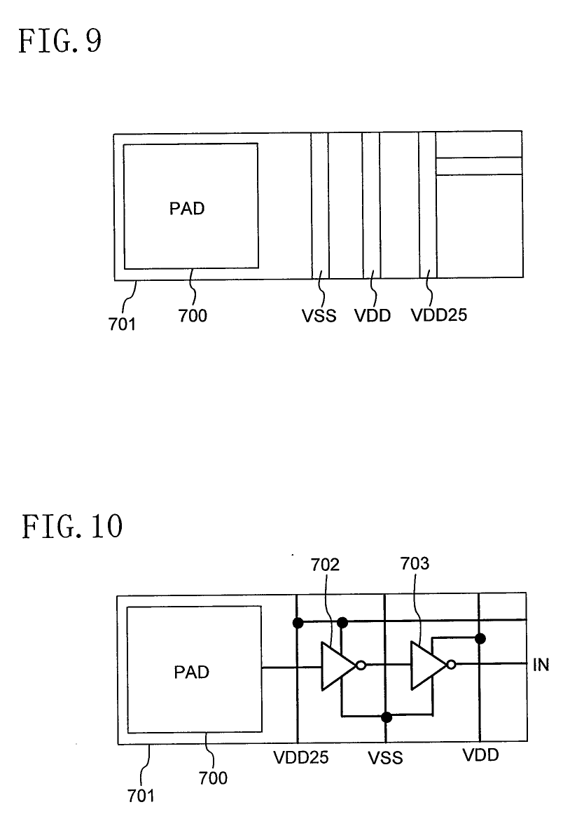

FIG. 9 is a plan view showing a layout of a single I/O cell in the system LSI, FIG. 10 is a circuit diagram of FIG. 9, showing a single I/O cell. FIGS. 9 and 10 show an I/O cell 701, including a VSS line, a VDD line, a VDD25 line as an I/O power supply line for supplying the power supply from VDD25, a pad 700 for connecting the I/O cell 701 to an external terminal, an inverter circuit 702 using VDD25 as its power supply, and another inverter circuit 703 using VDD as its power supply. The VDD25 power supply line is connected to the electrical fuse circuit by a line IN.

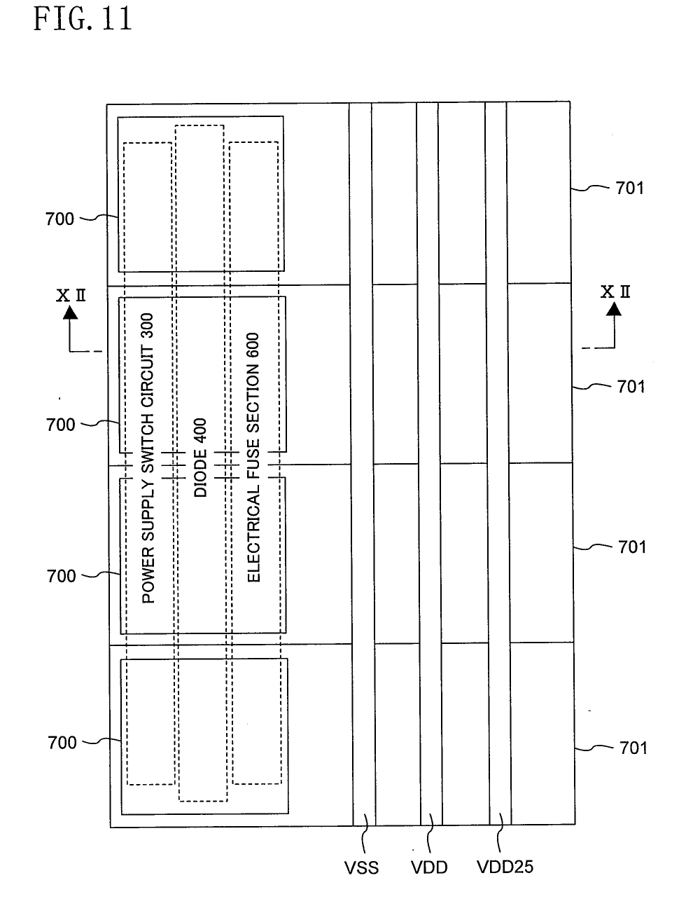

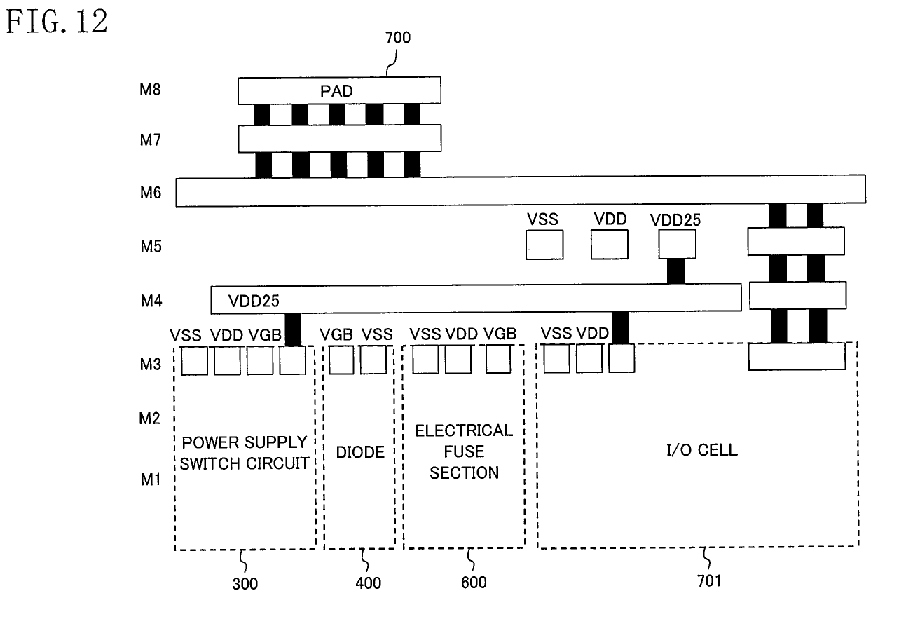

FIG. 11 is a plan view showing still another example of a system LSI including the electrical fuse circuit of FIG. 1 or 5, and FIG. 12 is a cross-sectional view taken along line XII-XII of FIG. 11. In the illustrated example, an electrical fuse circuit including the power supply switch circuit 300, the diode 400 and the electrical fuse section 600 is provided on a system LSI. Referring to FIGS. 11 and 12, each I/O cell 701 includes the pad 700 connected to an external terminal, the VSS line having the ground potential, the power supply VDD line, and the power supply VDD25 line. The power supply switch circuit 300, the diode 400 and the electrical fuse section 600 are each provided in a layer below the pad 700. The power supply switch circuit 300 is electrically connected to the power supply VDD25 line via a wiring layer M4. The provision of the power supply switch circuit 300, the diode 400 and the electrical fuse section 600 in a layer below the pad 700 wastes no circuit area and realizes a reduction in the total area of the system LSI.

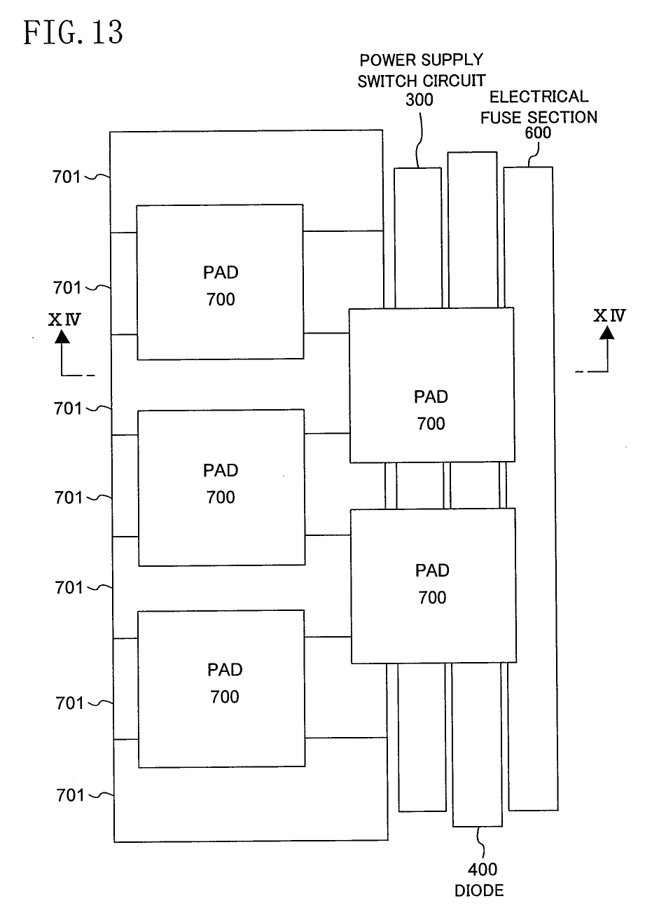

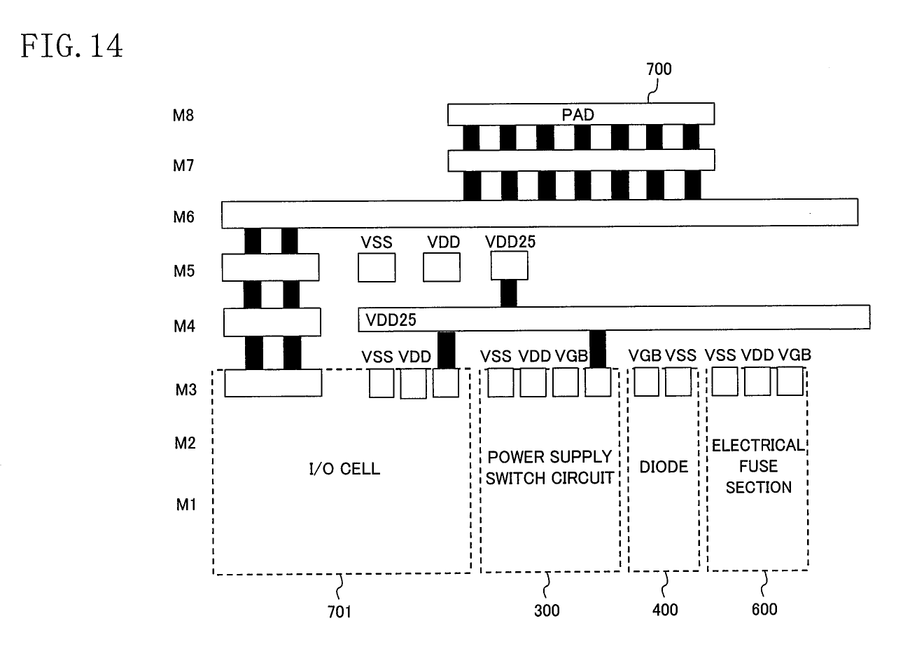

FIG. 13 is a plan view showing still another example of a system LSI including the electrical fuse circuit of FIG. 1 or 5, and FIG. 14 is a cross-sectional view taken along line XIV-XIV of FIG. 13. Also in this illustrated example, an electrical fuse circuit including the power supply switch circuit 300, the diode 400 and the electrical fuse section 600 is provided on a system LSI. Where the pads 700 are arranged in a staggered pattern as shown in FIGS. 13 and 14, there is produced a space below the pads 700 on the right side (the side closer to the center of the system LSI core). The power supply switch circuit 300, the diode 400 and the electrical fuse section 600 (including a plurality of electrical fuse bit cells 200 and the programming shift register block 100) are provided in this layer below the pad 700. The provision of the power supply switch circuit 300, the diode 400 and the electrical fuse section 600 in a layer below the pad 700 wastes no circuit area and realizes a reduction in the total area of the system LSI.

As described above, an electrical fuse circuit of the present invention includes an independent power supply switch circuit and a plurality of electrical fuse bit cells, wherein the electrical fuse bit cells can be made of LSI logic transistors (e.g., 1.2-V transistors), thus providing an advantage toward a reduction in the total area of the electrical fuse circuit. Moreover, with the provision of a diode between the output of the independent power supply switch circuit and the ground potential, it is possible to prevent a surge current from flowing into fuse elements upon ESD application, whereby it is possible to prevent fuse elements from being erroneously broken and to ensure the safety of an electrical fuse circuit.

An electrical fuse circuit of the present invention is useful in applications of memory devices with redundancy, secure ID applications for improving the security or protecting copyrights, chip ID applications for defect analysis of defective chips after assembly, for example, and analog trimming applications.

What is claimed is:

1. An electrical fuse circuit, in which a fuse element is broken by a current flow therethrough, comprising:
an independent power supply switch circuit;
a fuse element one end of which is connected to an output of the power supply switch circuit; and
a first MOS transistor connected to the other end of the fuse element.

2. The electrical fuse circuit of claim 1, comprising a plurality of fuse bit cells, each including the fuse element and the first MOS transistor.

3. The electrical fuse circuit of claim 1, wherein the power supply switch circuit includes a first switch transistor and a second switch transistor, and receives a first power supply voltage and a second power supply voltage smaller than the first power supply voltage, with one end of the first switch transistor being connected to the first power supply voltage, the other end thereof being connected to the output of the power supply switch circuit, one end of the second switch transistor being connected to the second power supply voltage, and the other end thereof being connected to the output of the power supply switch circuit.

4. The electrical fuse circuit of claim 3, wherein the first switch transistor is a PMOS transistor, and the second switch transistor comprises a CMOS transmission gate.

5. The electrical fuse circuit of claim 3, wherein the first power supply voltage is an I/O power supply voltage of an LSI, and the second power supply voltage is a logic power supply voltage of the LSI.

6. The electrical fuse circuit of claim 3, wherein a gate oxide film thickness of the first switch transistor and the second switch transistor of the power supply switch circuit is equal to that of an I/O circuit of an LSI.

7. The electrical fuse circuit of claim 1, wherein a diode is connected between a ground potential and the output of the power supply switch circuit, with an anode of the diode being connected to the ground potential and a cathode of the diode being connected to the output of the power supply switch circuit.

8. The electrical fuse circuit of claim 7, wherein the power supply switch circuit, the diode and the plurality of fuse bit cells are arranged in this order from an I/O power supply cell side of an LSI toward a center of the LSI.

9. The electrical fuse circuit of claim 7, wherein diodes are provided around the plurality of fuse bit cells, and the power supply switch circuit, the diode, the plurality of fuse bit cells and the diode are arranged in this order from an I/O power supply cell side of an LSI toward a center of the LSI.

10. The electrical fuse circuit of claim 7, wherein the power supply switch circuit or the diode or some of the plurality of fuse bit cells are provided in a layer below a pad connected to an external terminal of an LSI.

11. The electrical fuse circuit of claim 10, wherein pads connected to external terminals of an LSI are arranged in a staggered pattern, and the power supply switch circuit or the diode or some of the plurality of fuse bit cells are provided in a layer below those pads that are located on a side closer to a center of the LSI.

12. The electrical fuse circuit of claim 2, wherein a gate oxide film thickness of the plurality of fuse bit cells is equal to that of a logic transistor of an LSI.

13. The electrical fuse circuit of claim 3, wherein: a plurality of power supply switch circuits are provided in an LSI; a different first power supply voltage is input to each power supply switch circuit; the first switch transistors of the plurality of power supply switch circuits all have an equal gate length and an equal gate width; and the second switch transistors of the plurality of power supply switch circuits all have an equal gate length and an equal gate width.
